(19) United States
(12) Patent Application Publication
(10) Pub. No.: US 2008/0272410 A1
(43) Pub. Date: Nov. 6, 2008

(54) Self-Aligned Spacer Contact

(76) Inventor: Chung-Te Lin, Tainan City (TW)

Correspondence Address: SLATER & MATSIL, L.L.P., 17950 PRESTON ROAD, SUITE 1000, DALLAS, TX, 75252, US

(21) Appl. No.: 11/743,519

(22) Filed: May 2, 2007

(51) Int. Cl. H01L 29/76

(52) U.S. Cl. 257/288; 257/E29.226

(57) ABSTRACT

A metal-oxide-semiconductor field-effect transistor (MOSFET) having self-aligned spacer contacts is provided. In accordance with embodiments of the present invention, a transistor, having a gate electrode and source/drain regions formed on opposing sides of the gate electrode, is covered with a first dielectric layer. A first contact opening is formed in the first dielectric layer to expose at least a portion of one of the source/drain regions. A second dielectric layer is formed over the first dielectric layer. Thereafter, an inter-layer dielectric layer is formed over the second dielectric layer and a second contact opening is formed through the inter-layer dielectric layer. In an embodiment, an etch-back process may be performed on the second dielectric layer prior to forming the inter-layer dielectric layer.

### TECHNICAL FIELD

The present invention relates generally to semiconductor devices and, more particularly, to self-aligned spacer contacts and methods of manufacture.

### BACKGROUND

Size reduction of metal-oxide-semiconductor field-effect transistors (MOSFETs), including reduction of the gate length and gate oxide thickness, has enabled the continued improvement in speed, performance, density, and cost per unit function of integrated circuits over the past few decades. As the size of MOSFETs has decreased, however, so has the design margins.

For example, as the size of MOSFETs has decreased, the acceptable margin for error in the alignment of a contact has also decreased. Generally, a MOSFET comprises a gate dielectric layer and a gate electrode overlying a silicon substrate. One or more, typically at least two, implants are used to form source/drain regions in the substrate on opposing sides of the gate dielectric layer and the gate electrode. Spacers may also be used to form implants having varying concentrations offset from the gate dielectric and the gate electrode. Thereafter, an inter-layer dielectric is formed over the substrate, gate electrode and source/drain regions. One or more metal layers may be formed, including interconnections between the various metal layers. Vias are formed in the inter-layer dielectric to form an electrical connection between the source/drain regions and the overlying metal layers. If the via is misaligned with the source/drain regions, however, the transistor may become shorted.

In particular, as designs shrink, a via connecting to the source/drain regions may become shorted to the gate electrode if the via is misaligned. Generally, this occurs when the etching process through the inter-layer dielectric is misaligned such that the via exposes portions of the gate electrode. As a result, when the via is filled with a conductive material, the gate electrode becomes shorted to the source/drain regions, thereby reducing yields and increasing costs.

Therefore, there is a need for a contact structure, and a manufacturing method, to reduce or prevent the above-described shorting.

### SUMMARY OF THE INVENTION

These and other problems are generally reduced, solved or circumvented, and technical advantages are generally achieved, by embodiments of the present invention, which provides self-aligned spacer contacts and a method of manufacture.

In an embodiment of the present invention, a metal-oxide-semiconductor field-effect transistor (MOSFET) having self-aligned spacer contacts is provided. The MOSFET comprises a first dielectric layer formed over a transistor. A first contact opening is formed through the first dielectric layer and a second dielectric layer is formed over the first contact opening. An inter-layer dielectric is formed over the substrate and a second contact opening is formed. In an embodiment, the second dielectric layer is etched to form spacers on sidewalls of the first contact opening.

In another embodiment of the present invention, a MOSFET having self-aligned spacer contacts is provided. The MOSFET comprises a first dielectric layer formed over a transistor. A first contact opening is formed through the first dielectric layer and spacers formed along sidewalls of the first contact opening. An inter-layer dielectric is formed over the substrate and a second contact opening is formed such that the second contact opening at least partially overlaps the first contact opening.

In yet another embodiment of the present invention, a MOSFET having self-aligned spacer contacts is provided. The MOSFET comprises a first dielectric layer formed over a transistor. A first contact opening is formed through the first dielectric layer and a second dielectric layer is formed along sidewalls of the first contact opening. An inter-layer dielectric is formed over the substrate and a second contact opening is formed such that the second contact opening at least partially overlaps the first contact opening.

It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The object and other advantages of this invention are best described in the preferred embodiment with reference to the attached drawings that include:

FIGS. 1-6 illustrate various process steps of fabricating a MOSFET device having self-aligned spacer contacts in accordance with an embodiment of the present invention;

FIGS. 7-9 illustrate various process steps of fabricating a MOSFET device having self-aligned spacer contacts in accordance with another embodiment of the present invention; and

FIG. 10 illustrates transistors having different stress layers in accordance with another embodiment of the present invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

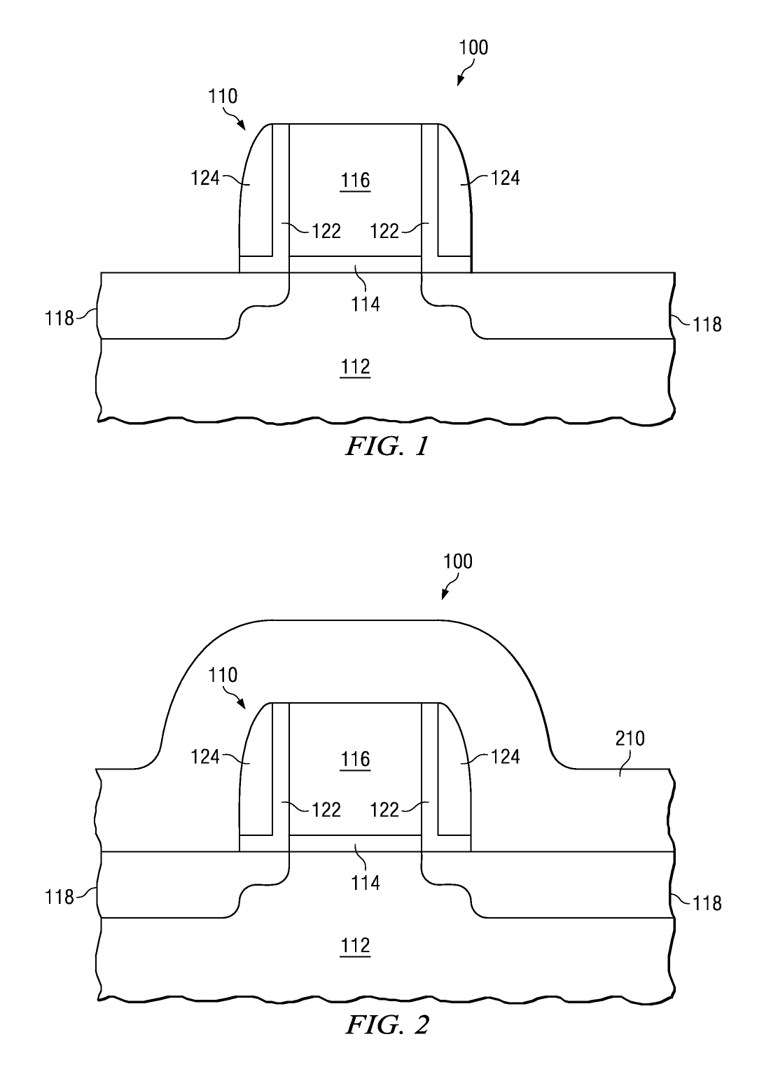

FIGS. 1-6 illustrate a method embodiment for fabricating a semiconductor device in accordance with an embodiment of the present invention. Embodiments of the present invention illustrated herein may be used in a variety of circuits. Referring first to FIG. 1, a wafer 100 is shown comprising substrate 112 having a transistor 110 formed thereon. The substrate 112 may comprise bulk silicon, doped or undoped, or an active layer of a semiconductor-on-insulator (SOI) substrate. Generally, an SOI comprises a layer of a semiconductor material, such as silicon, formed on an insulator layer. The insulator layer may be, for example, a buried oxide (BOX) layer or a silicon oxide layer. The insulator layer is provided on a substrate, typically a silicon or glass substrate. Other substrates, such as a multi-layered or gradient substrate may also be used.

A gate dielectric 114 and a gate electrode 116 are formed and patterned as is known in the art on the substrate 112. The gate dielectric 114 is preferably a high-K dielectric material, such as silicon oxide, silicon oxynitride, silicon nitride, an oxide, a nitrogen-containing oxide, a combination thereof, or the like. Preferably, the gate dielectric 114 has a relative permittivity value greater than about 4. Other examples of such materials include aluminum oxide, lanthanum oxide, hafnium oxide, zirconium oxide, hafnium oxynitride, or combinations thereof.

In an embodiment in which the gate dielectric 114 comprises an oxide layer, the gate dielectric 114 may be formed by any oxidation process, such as wet or dry thermal oxidation in an ambient comprising an oxide, H₂O, NO, or a combination thereof, or by chemical vapor deposition (CVD) techniques using tetra-ethyl-ortho-silicate (TEOS) and oxygen as a precursor. In the preferred embodiment, the gate dielectric 114 is about 8 Å to about 50 Å in thickness.

The gate electrode 116 preferably comprises a conductive material, such as a metal (e.g., tantalum, titanium, molybdenum, tungsten, platinum, aluminum, hafnium, or ruthenium), a metal silicide (e.g., titanium silicide, cobalt silicide, nickel silicide, or tantalum silicide), a metal nitride (e.g., titanium nitride or tantalum nitride), doped poly-crystalline silicon, other conductive materials, or a combination thereof. In one example, amorphous silicon is deposited and recrystallized to create poly-crystalline silicon (poly-silicon). In the preferred embodiment in which the gate electrode is poly-silicon, the gate electrode 116 may be formed by depositing doped or undoped poly-silicon by low-pressure chemical vapor deposition (LPCVD) to a thickness in the range of about 400 Å to about 2500 Å, but more preferably about 800 Å.

The gate dielectric 114 and the gate electrode 116 may be patterned by photolithography techniques as are known in the art. Generally, photolithography involves depositing a photoresist material, which is then masked, exposed, and developed. After the photoresist mask is patterned, an etching process may be performed to remove unwanted portions of the gate dielectric material and the gate electrode material to form the gate dielectric 114 and the gate electrode 116 as illustrated in FIG. 1. In the preferred embodiment in which the gate electrode material is poly-crystalline silicon and the gate dielectric material is an oxide, the etching process may be a wet or dry, anisotropic or isotropic, etch process, but preferably is an anisotropic dry etch process.

Source/drain regions 118 may be formed by ion implantation. The source/drain regions 118 may be implanted with an n-type dopant, such as phosphorous, nitrogen, arsenic, antimony, or the like, to fabricate NMOS devices or may be implanted with a p-type dopant, such as boron, aluminum, indium, and the like, to fabricate PMOS devices. Optionally, NMOS devices may be fabricated on the same chip as PMOS devices. In this optional embodiment, it may be necessary to utilize multiple masking and ion implant steps as are known in the art, such that only specific areas are implanted with n-type and/or p-type ions.

Liners 122 and spacers 124 form spacers for a second ion implant in the source/drain regions 118. The liners 122 are preferably a substantially conformal oxide layer. In an embodiment, the liners 122 comprise an oxide, such as a silicon dioxide layer formed by atomic-layer deposition (ALD) techniques known in the art. Other methods, such as chemical vapor deposition (CVD), low-pressure CVD (LPCVD), or the like, and other materials, such as silicon oxynitride, silicon, a combination thereof, or the like, may also be used. In the preferred embodiment, the liners 122 are about 20 Å to about 100 Å in thickness, but more preferably larger than about 20 Å in thickness.

The spacers 124 preferably comprise silicon nitride (Si₃N₄), or a nitrogen containing layer other than Si₃N₄, such as SiₓN_{y}, silicon oxynitride SiOₓN_{y}, silicon oxime SiOₓN_{y}:H_{z}, or a combination thereof. In a preferred embodiment, the spacers 124 are formed from a layer comprising Si₃N₄ that has been formed using CVD techniques using silane and ammonia as precursor gases. The liners 122 and spacers 124 may be patterned by performing an isotropic or anisotropic etch process as is known in the art.

It should be noted that a silicidation process may be performed. The silicidation process may be used to improve the conductivity and decrease the resistance of the gate electrode 116, and the source/drain regions 118. The silicide may be formed by depositing a metal layer such as titanium, nickel, tungsten, or cobalt via plasma vapor deposition (PVD) procedures. An anneal procedure causes the metal layer to react with the gate electrode 116 and the source/drain regions 118 to form a metal silicide. Portions of the metal layer overlying insulator spacers 124 remain unreacted. Selective removal of the unreacted portions of the metal layer may be accomplished, for example, via wet etch procedures. An additional anneal cycle may be used if desired to alter the phase of silicide regions, which may result in a lower resistance.

It should also be noted that the above description is but one example of a transistor 110 that may be used with an embodiment of the present invention. Other transistors and other semiconductor devices may also be used. For example, the transistor may have raised source/drains, the transistor may be a split-gate transistor or a FinFET design, different materials and thicknesses may be used, different source/drain implant profiles may be used, different spacer/liner structures may be used, and/or the like.

FIG. 2 illustrates the wafer 100 after a first dielectric layer 210 has been formed thereon, covering the transistor 110 in accordance with an embodiment of the present invention. It should be noted that the first dielectric layer 210 may be a high-stress film, imparting either a tensile-stress film or a compressive-stress film. A tensile-stress film results in tensile strain in the channel region and enhances electron mobility of an n-channel transistor, and a compressive-stress film results in compressive strain in the channel region and enhances hole mobility of a p-channel transistor.

The first dielectric layer 210 may be formed, for example, of silicon nitride by a CVD process, a PVD process, an ALD process, or the like to a thickness between about 250 Å to about 1000 Å. Materials that may be suitable for use as a tensile-stress film include SiN, oxide, oxynitride, SiC, SiCN, Ni silicide, Co silicide, combinations thereof, and the like. Materials that may be suitable for use as a compressive-stress film include SiGe, SiGeN, nitride, oxide, oxynitride, combinations thereof, and the like. In an embodiment, the tensile-stress film is a tensile silicon nitride film, and the compressive-stress film is a compressive silicon nitride film.

It should be noted that the first dielectric layer 210 may comprise a plurality of layers of either the same or different materials having the same or different stress characteristics. Furthermore, it should be noted that embodiments of the present invention may be used to fabricate wafers having both NMOS and PMOS devices thereon. For example, high-stress films may be formed and patterned individually by known deposition and patterning techniques to create NMOS transistors having a tensile-stress film and PMOS transistors having a compressive-stress film on the same wafer. This allows each transistor to be independently customized for its particular function.

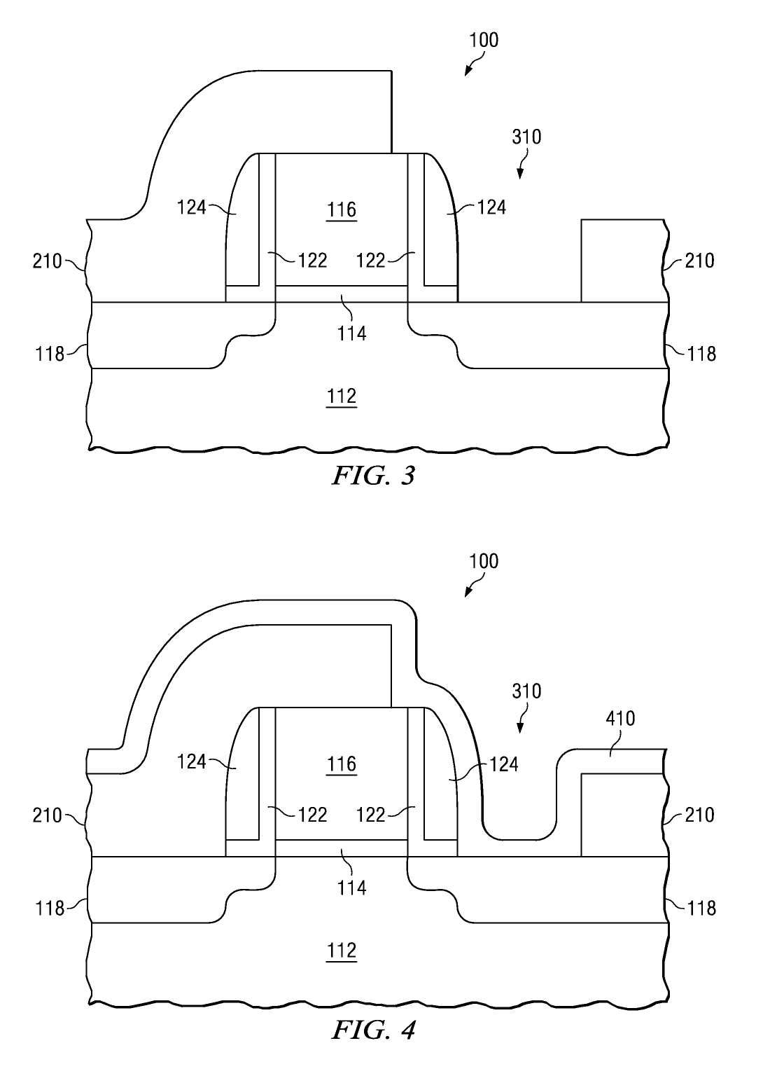

FIG. 3 illustrates the wafer 100 after a first contact opening 310 has been formed through the first dielectric layer 210 in accordance with an embodiment of the present invention. The first contact opening 310 may be formed by photolithography techniques known in the art. In the present case, a photoresist material is deposited and patterned to expose portions of the first dielectric layer 210 corresponding to the first contact opening 310. Thereafter, the first contact opening 310 may be formed by etching the exposed portions of the contact opening 310. In an embodiment in which the first dielectric layer 210 comprises silicon nitride, the contact opening 310 may be patterned by performing an isotropic or anisotropic etch process, such as an isotropic etch process using a solution of phosphoric acid (H₃PO₄).

It should be noted that FIG. 3 illustrates the situation in which the first contact opening is misaligned such that a portion of the gate electrode 116 is exposed. As one of ordinary skill in the art will appreciate, such a misalignment may result in a short between the gate electrode 116 and the source/drain regions 118 if the first contact opening 310 is filled with a conductive material. As explained in greater detail in the following paragraphs, a second dielectric layer is formed to prevent or reduce the chances of a short from occurring.

FIG. 4 illustrates the wafer 100 after a second dielectric layer 410 has been formed in accordance with an embodiment of the present invention. In an embodiment, the second dielectric layer 410 comprises silicon nitride formed by CVD, PVD, ALD, or the like to a thickness between about 250 Å to about 1000 Å. Other materials that may be used include dielectric materials such as SiN, oxide, oxynitride, SiC, SiCN, Ni silicide, Co silicide, SiGe, SiGeN, combinations thereof, and the like.

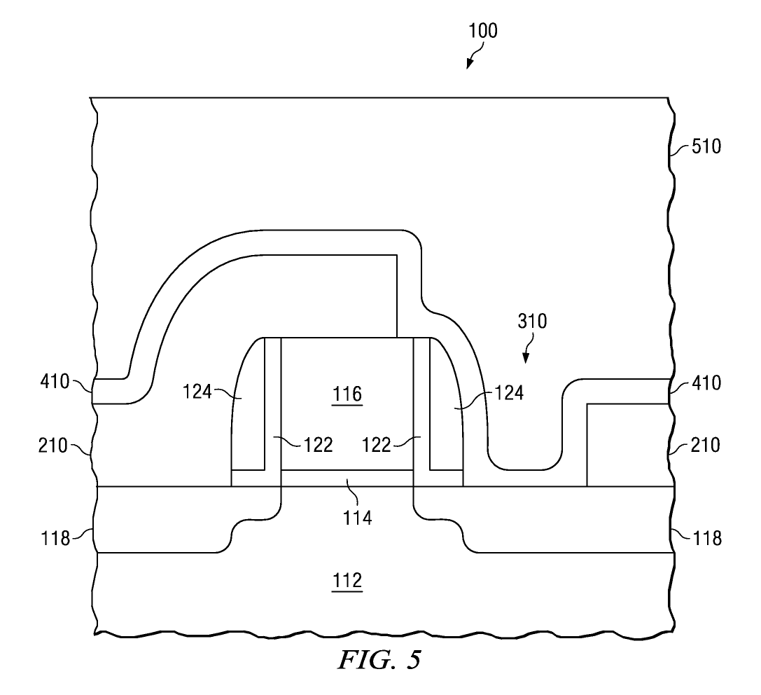

FIG. 5 illustrates the wafer 100 after an inter-layer dielectric (ILD) layer 510 has been formed in accordance with an embodiment of the present invention. In an embodiment, the ILD layer 510 may be formed, for example, of a low-K dielectric material, such as silicon oxide, borophosphosilicate glass (BPSG), phosphosilicate glass (PSG), fluorinated silicate glass (FSG), carbon-doped silicon oxide, or the like, by any suitable method known in the art. In an embodiment, the ILD layer 510 comprises BPSG or PSG that may be formed by CVD techniques to a thickness from about 2000 Å to about 8000 Å. Other thicknesses and materials may be used. A planarization process, such as a chemical mechanical polishing (CMP) process may be performed.

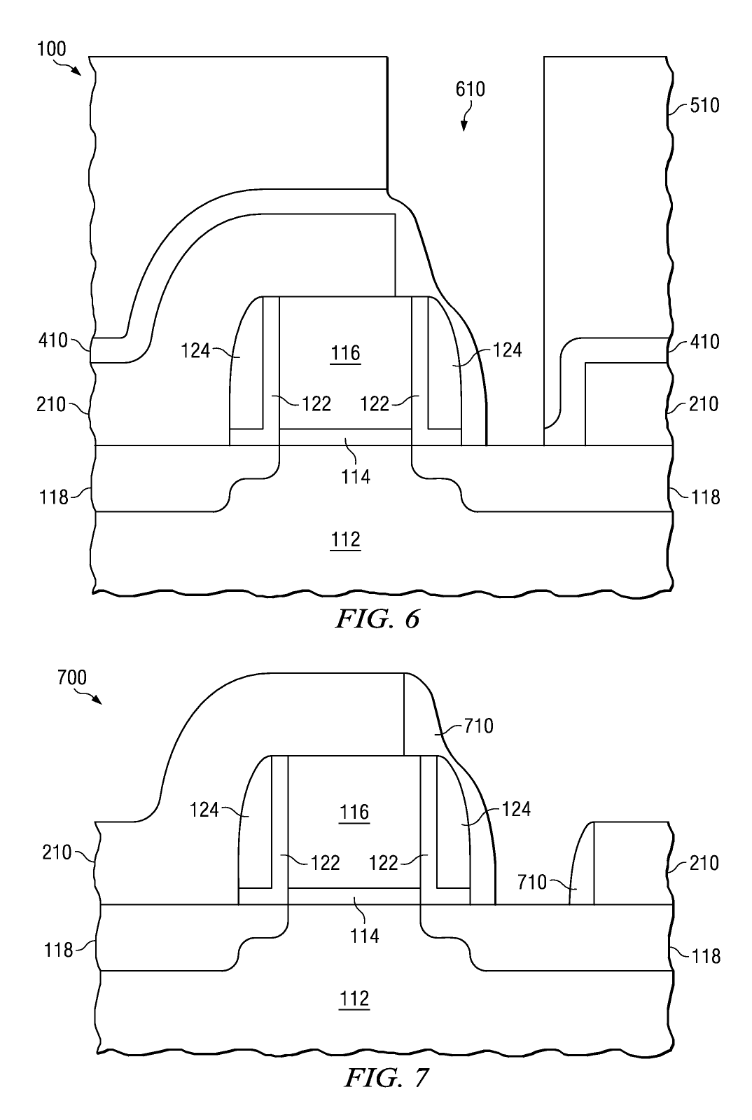

FIG. 6 illustrates the wafer 100 after a contact etch process has been performed to form a second contact opening 610 in accordance with an embodiment of the present invention. The second contact opening 610 may be formed by photolithography techniques known in the art by depositing and patterning a photoresist layer to expose a portion of the ILD layer 510 corresponding to the desired position of the second contact opening 610. Thereafter, the ILD layer 510 and the underlying second dielectric layer 410 may be etched using an anisotropic etching process.

Thereafter, standard processes may be used to complete fabrication and packaging of the semiconductor device. For example, the second contact opening 610 may be filled with a conductive material, inter-layer dielectrics and metal layers may be formed and patterned, other circuitry may be formed, the wafer may be diced and packaged, and the like.

FIG. 6 also illustrates that the second contact opening 610 may be misaligned. In this case, the second contact opening 610 is not only misaligned with respect to the source/drain regions 118, but also misaligned with respect to the first contact opening 310 (see FIG. 5). As one of ordinary skill in the art will appreciate, however, because the first contact opening 310 was formed prior to forming the ILD layer 510 and the second dielectric layer 410 was formed in the first contact opening 310, the second dielectric layer 410 protects the gate electrode 116 from becoming shorted by a subsequently formed conductive layer within the second contact opening 610.

FIGS. 7-9 illustrate a second embodiment of the present invention. Referring first to FIG. 7, a portion of a wafer 700 is illustrated. In particular, the wafer 700 illustrates wafer 100 as illustrated in FIG. 4, wherein like reference numerals refer to like elements, after an etch-back process has been performed. The etch-back process forms contact spacers 710 from the second dielectric layer 410 (see FIG. 4). It should be noted that in an embodiment the first dielectric layer 210 and the second dielectric layer 410 are formed of silicon nitride. In this embodiment, the etch-back process may be performed using a solution of HF.

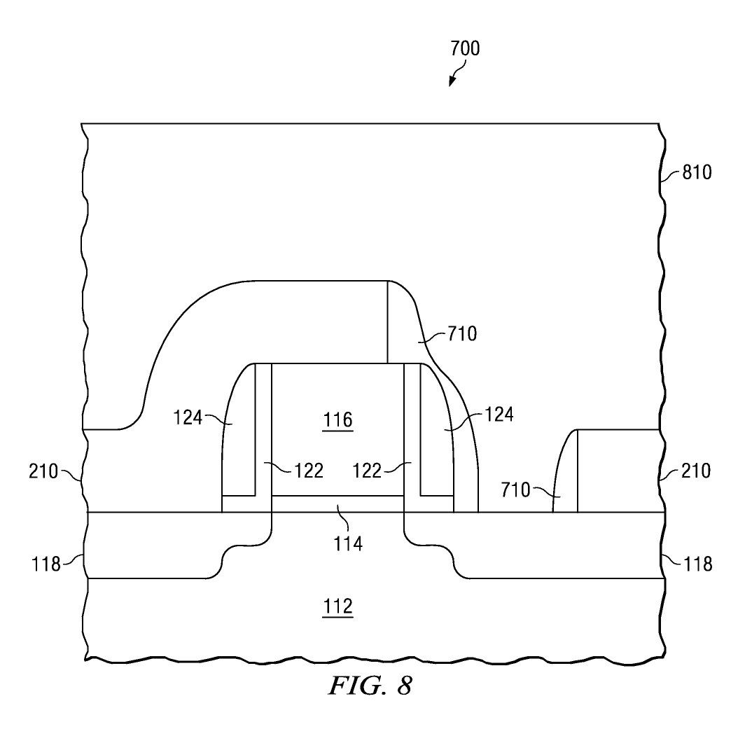

FIG. 8 illustrates wafer 700 after an inter-layer dielectric (ILD) layer 810 has been formed in accordance with an embodiment of the present invention. In an embodiment, the ILD layer 810 may be formed, for example, of a material and in a manner similar to the ILD layer 510 discussed above with reference to FIG. 5.

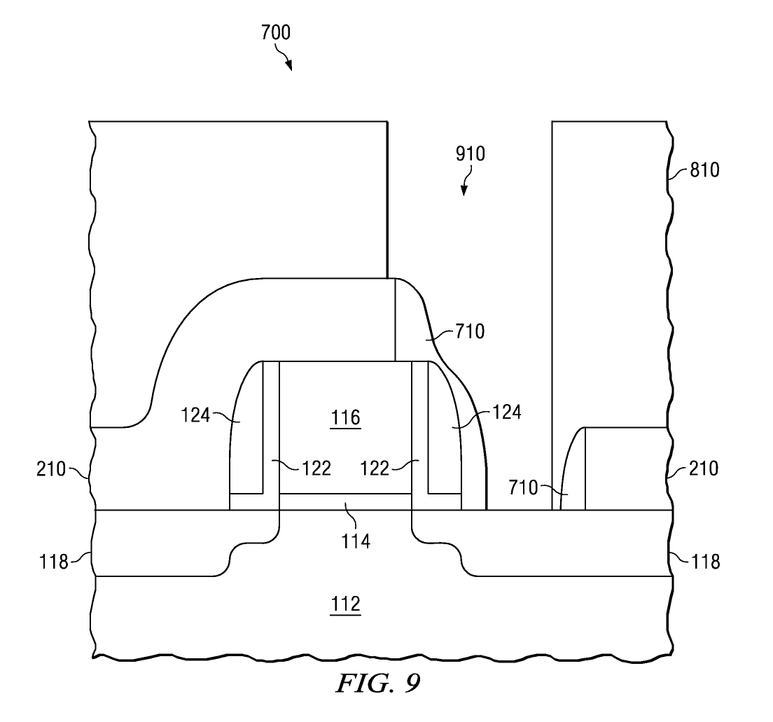

FIG. 9 illustrates wafer 700 after a contact etch process has been performed to form a second contact opening 910 in accordance with an embodiment of the present invention. In an embodiment, the second contact opening 910 may be formed, for example, in a similar manner as the second contact opening 610 discussed above with reference to FIG. 6.

Thereafter, standard processes may be used to complete fabrication and packaging of the semiconductor device. For example, the second contact opening 910 may be filled with a conductive material, inter-layer dielectrics and metal layers may be formed and patterned, other circuitry may be formed, the wafer may be diced and packaged, and the like.

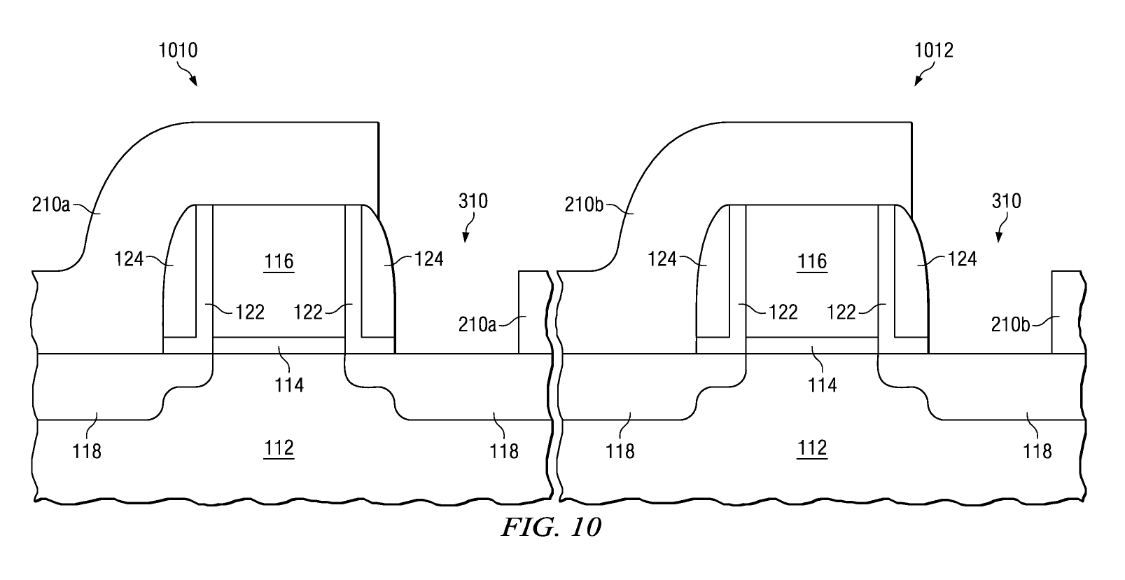

As discussed above, the first dielectric layer 210 may exhibit different characteristics for different devices. For example, FIG. 10 illustrates an embodiment of the present invention in which the first dielectric layer 210 includes a first stress film 210a formed over a first transistor 1010 and a second stress film 210b formed over a second transistor 1012. In an embodiment, the first stress film 210a and the second stress film 210b are formed by first depositing a blanket layer of a suitable dielectric material for the first stress film 210a and then removing the first stress film 210a from over the second transistor 1012 using photolithography and etching techniques. A similar process may be used to deposit a suitable dielectric material for the second stress film 210b and then removing the second stress film 210b from over the first transistor 1010 using photolithography and etching techniques. It should be noted that the first and second contact openings 310, 910 may be formed simultaneously as removing unwanted portions of the stress layer from the other transistor.

In an embodiment, the first transistor 1010 is an NMOS transistor and the first stress film 210a is a tensile-stress silicon nitride film, and the second transistor 1012 is a PMOS transistor and the second stress film 210b is a compressive-stress silicon nitride film.

Thereafter, processing similar to that discussed above with reference to FIGS. 4-6 and 7-9 may be performed.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A semiconductor device comprising:
a transistor on a substrate, the transistor comprising a gate electrode and source/drain regions on opposing sides of the gate electrode;
a first dielectric layer over the transistor;
a first contact opening in the first dielectric layer over at least a portion of one of the source/drain regions;
a second dielectric layer along sidewalls of the first contact opening;
an inter-layer dielectric (ILD) layer over the first dielectric layer; and
a second contact opening at least partially within the first contact opening.

2. The semiconductor device of claim 1, wherein the first dielectric layer comprises silicon nitride.

3. The semiconductor device of claim 1, wherein the second dielectric layer along sidewalls of the first contact opening extends over at least a portion of the gate electrode.

4. The semiconductor device of claim 1, wherein the second dielectric layer comprises silicon nitride.

5. The semiconductor device of claim 1, wherein the second dielectric layer comprises spacers alongside the first contact opening.

6. The semiconductor device of claim 1, wherein the first dielectric layer has a thickness from about 200 Å to about 1000 Å.

7. The semiconductor device of claim 1, wherein the second dielectric layer has a thickness from about 40 Å to about 400 Å.

8. The semiconductor device of claim 1, wherein the first dielectric layer comprises a high stress film.

9. A semiconductor device comprising:
a PMOS transistor on a substrate, the PMOS transistor comprising a first gate electrode and first source/drain regions on opposing sides of the first gate electrode;
an NMOS transistor on the substrate, the NMOS transistor comprising a second gate electrode and second source/drain regions on opposing sides of the second gate electrode;
a first stress layer over the PMOS transistor, the first stress layer being a compressive stress film;
a first contact opening in the first stress layer over at least a portion of one of the first source/drain regions;
a second stress layer over the NMOS transistor, the second stress layer being a tensile stress film;
a second contact opening in the second stress layer over at least a portion of one of the second source/drain regions;
a first dielectric layer over the first stress layer and the second stress layer;
an inter-layer dielectric (ILD) layer over the first dielectric layer;
a third contact opening through the ILD layer at least partially within the first contact opening; and
a fourth contact opening through the ILD layer at least partially within the second contact opening.

10. The semiconductor device of claim 9, wherein the first dielectric layer comprises silicon nitride.

11. The semiconductor device of claim 9, wherein the first dielectric layer comprises spacers alongside the first contact opening and the second contact opening, the first dielectric layer not extending over a bottom surface of the first contact opening and a bottom surface of the second contact opening.

12. The semiconductor device of claim 9, wherein the first stress layer and the second stress layer have a thickness from about 200 Å to about 1000 Å.

13. The semiconductor device of claim 9, wherein the first dielectric layer has a thickness from about 40 Å to about 400 Å.

14. A semiconductor device comprising:
a transistor on a substrate, the transistor comprising a gate electrode and source/drain regions on opposing sides of the gate electrode;
a first dielectric layer over the transistor;
a first contact opening in the first dielectric layer over at least a portion of one of the source/drain regions;
spacers along sidewalls of the first contact opening;
an inter-layer dielectric (ILD) layer over the first dielectric layer; and
a second contact opening at least partially within the first contact opening.

15. The semiconductor device of claim 14, wherein the first dielectric layer comprises silicon nitride.

16. The semiconductor device of claim 14, wherein the spacers comprise silicon nitride.

17. The semiconductor device of claim 14, wherein the first dielectric layer has a thickness from about 200 Å to about 1000 Å.

18. The semiconductor device of claim 14, wherein the spacers have a thickness from about 40 Å to about 400 Å.

19. The semiconductor device of claim 14, wherein the first dielectric layer comprises a high stress film.

20. The semiconductor device of claim 14, wherein the first dielectric layer comprises a compressive stress film.
